(19) United States
(12) Patent Application Publication
(10) Pub. No.: US 2016/0293513 A1
(43) Pub. Date: Oct. 6, 2016

(54) SEMICONDUCTOR DEVICE HAVING A HEAT TRANSFER PATH THROUGH A GROUND LAYER

(71) Applicant: KABUSHIKI KAISHA TOSHIBA, Tokyo (JP)

(72) Inventor: Tatsuro HIRUTA, Kamakura Kanagawa (JP)

(21) Appl. No.: 14/837,955

(22) Filed: Aug. 27, 2015

(30) Foreign Application Priority Data
Mar. 30, 2015 (JP) 2015-070397

(51) Int. Cl. H01L 23/367; H01L 21/56; H01L 21/48; H01L 23/498; H01L 23/31

(52) U.S. Cl. CPC H01L 23/3672; H01L 23/49816; H01L 23/49827; H01L 23/49838; H01L 23/3114; H01L 21/4871; H01L 21/4853; H01L 21/486; H01L 21/565

(57) ABSTRACT

A semiconductor device includes a first substrate including a surface layer and a ground layer, the surface layer including a plurality of first vias that is exposed on a surface of the first substrate and electrically connected to the ground layer, a second substrate disposed on the first substrate and including a plurality of second vias penetrating through the second substrate, a plurality of conduction elements, each disposed between one of the first vias and one of the second vias, a semiconductor device unit disposed on the second substrate, and a heat transfer layer covering the semiconductor device unit and in contact with the second vias at a periphery of the semiconductor device unit, such that heat generated by the semiconductor device unit is transferred to the ground layer, through the heat transfer layer, the second vias, the conduction elements, and the first vias.

### CROSS-REFERENCE TO RELATED APPLICATION

This application is based upon and claims the benefit of priority from Japanese Patent Application No. 2015-070397, filed Mar. 30, 2015, the entire contents of which are incorporated herein by reference.

### FIELD

Embodiments described herein relate generally to a semiconductor device, in particular, a semiconductor device having a heat transfer path through a ground layer.

### BACKGROUND

A semiconductor device which includes a heat radiating structure is known.

### DESCRIPTION OF THE DRAWINGS

FIG. 1 is a partial plan view of a semiconductor device according to a first embodiment.

FIG. 2 is a partial cross-sectional view of the semiconductor device according to the first embodiment.

FIG. 3 is a plan view of the semiconductor device, showing arrangement of a first electronic component (semiconductor package) and a second electronic component.

FIG. 4 is a partial plan view of the semiconductor device, showing arrangement of vias.

FIG. 5 is a partial plan view of the semiconductor device showing another arrangement of vias.

FIG. 6 is a partial plan view of a semiconductor device according to a second embodiment.

FIG. 7 is a partial cross-sectional view of the semiconductor device according to the second embodiment.

FIG. 8 is a plan view of the semiconductor device, showing arrangement of a first electronic component (semiconductor package) and a second electronic component.

FIG. 9 is a plan view of the semiconductor device, showing another arrangement of the first electronic component (semiconductor package) and the second electronic component.

FIG. 10 is a partial plan view of the semiconductor device, showing another arrangement of heat transfer units.

FIG. 11 is a partial plan view of the semiconductor device, showing another arrangement of the heat transfer units.

FIG. 12 is a plan view of a semiconductor package including a plurality of connection units which is thermally connected to a heat conduction layer and the heat transfer units which are connected to a portion of the connection units in the semiconductor device according to the second embodiment.

FIG. 13 is a partial cross-sectional view of a semiconductor device according to a third embodiment.

FIG. 14 is a partial cross-sectional view of a semiconductor device according to a fourth embodiment.

FIG. 15 is a perspective view of an electronic apparatus according to a fifth embodiment.

FIG. 16 is a perspective view of an electronic apparatus according to a sixth embodiment.

### DETAILED DESCRIPTION

One embodiment provides a semiconductor device having improved heat radiation efficiency.

In general, according to one embodiment, a semiconductor device includes a first substrate including a surface layer and a ground layer, the surface layer including a plurality of first vias that is exposed on a surface of the first substrate and electrically connected to the ground layer, a second substrate disposed on the first substrate and including a plurality of second vias penetrating through the second substrate, a plurality of conduction elements, each disposed between one of the first vias and one of the second vias, a semiconductor device unit disposed on the second substrate, and a heat transfer layer covering the semiconductor device unit and in contact with the second vias at a periphery of the semiconductor device unit, such that heat generated by the semiconductor device unit is transferred to the ground layer, through the heat transfer layer, the second vias, the conduction elements, and the first vias.

Hereinafter, with reference to the accompanied drawings, semiconductor devices and electronic apparatuses according to the exemplary embodiments will be described in detail.

In the disclosure, some elements are described using a plurality of expressions. These expressions are used only as examples, and other possible expressions may be used. Other elements which are not described using a plurality of expressions may also be described using other expressions.

Further, the drawings are schematically illustrated, and thus relationships between thicknesses and surface-areal sizes, ratios of each layer in thicknesses and the like may be different from those in actual dimensions. Further, in the relationships between drawings, sizes or ratios of each element may be partly different from each other.

### First Embodiment

A semiconductor device 10 according to a first embodiment is, for example, a solid state drive (SSD) device which is a mass data storage device using nonvolatile semiconductor memory such as a NAND type flash memory.

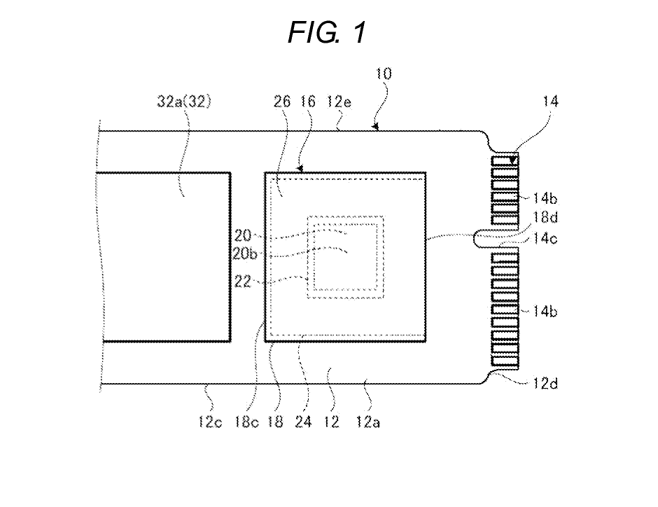

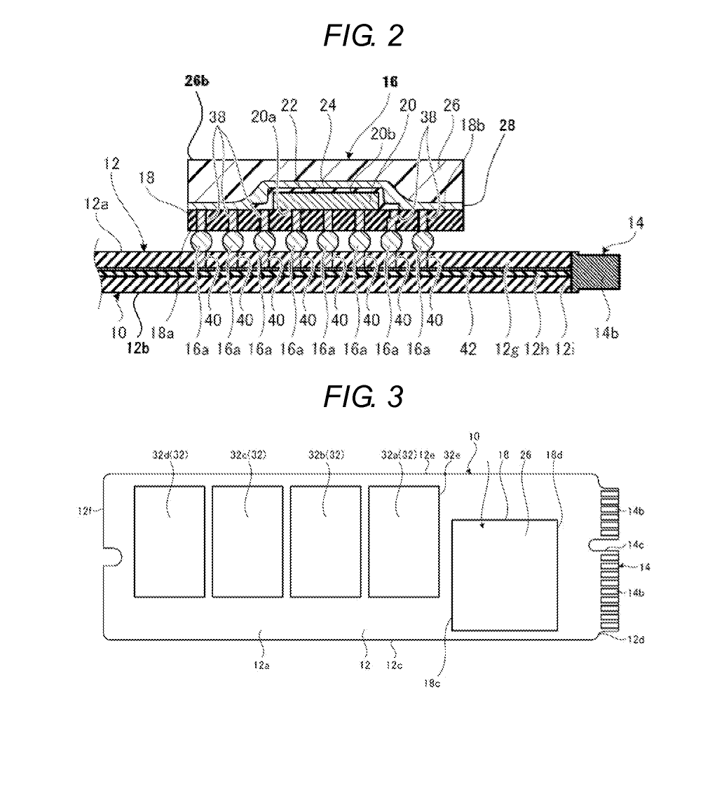

As shown in FIG. 1 to FIG. 3, the semiconductor device 10 configured as the SSD device includes, for example, a first substrate 12 (a printed wiring board: PWB, a bare board, and a raw board). The first substrate 12 is a planar plate-like component which includes a first surface 12a (mounting surface, first substrate surface, and top surface), a rear surface 12b (as shown in FIG. 2) (lower surface and bottom surface) which is opposite to the first surface 12a, and side surfaces 12c, 12d, 12e and 12f.

The first substrate 12 has a multilayer structure which is formed such that synthetic resin layers are repeatedly overlapped to be, for example, an eight-layer structure. Wiring patterns of various shapes are formed on the surface of each layer. For example, a signal layer that performs transmission and reception of signals, a ground layer, a power source layer, and the like may be formed on each layer. In FIG. 2, for simple illustration, a three-layer structure (a first layer 12g, a second layer 12h, and a third layer 12i) is shown. The ground layer 42 is disposed between the first layer 12g and the second layer 12h.

Further, types of wiring patterns in each layer may be appropriately modified. For example, wiring patterns of different types may be formed in one same layer, or there may be a layer having no wiring pattern.

Further, according to another embodiment, the first substrate 12 may be a single-sided substrate (one-layer substrate) or double-sided substrate (two-layer substrate). When the first substrate 12 is the single-sided substrate, a ground pattern, a signal pattern, a power source pattern, and the like are formed on the first surface 12a. When the first substrate 12 is the double-sided substrate, a ground pattern, a signal pattern, a power source pattern, and the like are appropriately distributed and formed on the first surface 12a and the rear surface 12b. For example, the side surface 12d of the first substrate 12 has a connector 14 (an interface, Serial ATA (SATA), or a junction plug) that is configured to be connected to external apparatuses, such as a personal computer, a CPU core, or the like.

The ground layer 42 formed in the inner layer of the first substrate 12, a signal layer (not shown), and a power source layer (not shown) are electrically connected to a predetermined terminal pin 14b of the connector 14 so as to be connected to an external apparatus. In the connector 14, for example, a slit 14c is formed in a position which is offset from the central position. The slit 14c is suited for fitting with a protrusion (not shown) provided on an external apparatus. According to the measure, the semiconductor device 10 may be protected from being fitted on backwards.

Further, according to another embodiment, a ground line (not shown herein) may be formed on the surface of the first surface 12a of the first substrate 12, and the ground line may be electrically connected to a predetermined terminal pin 14b of the connector 14 so as to be connected to an external apparatus. Further, for example, an internal wiring of the first substrate 12 or the like may be used to electrically connect a portion of the ground layer 42 and the ground line with each other.

Further, the ground layer 42 and the ground line are electrically connected to an external apparatus through the terminal pin 14b and electrically grounded. Further, heat transferred (thermally transferred) to the ground layer 42 or the ground line is transferred (thermally transferred) to a housing side of an external apparatus through the terminal pin 14b so that the heat generated in the semiconductor device 10 can be radiated.

A semiconductor package 16, which is a main component of the semiconductor device 10, is disposed on the first surface 12a of the first substrate 12. As shown in FIG. 2, the semiconductor package 16 includes the second substrate 18 (package substrate or BGA substrate), a semiconductor chip 20 (first electronic component, Si chip, or controller), an insulator layer 22 (insulator or insulation sheet), a heat conduction layer 24 (heat conduction body or heat conduction sheet), a sealing unit 26 (mold, reinforcing material, or cover).

The second substrate 18 is provided on the first surface 12a with solder balls 16a therebetween. Further, the second substrate 18 has a second surface 18a facing the first surface 12a, a third surface 18b opposite to the second surface 18a, and second vias 38 which penetrate between the second surface 18a and the third surface 18b.

Similarly to the first substrate 12, the second substrate 18 has a multilayer structure which is formed such that synthetic resin layers are repeatedly overlapped, which, however, is not shown. Wiring patterns of various shapes are formed on the surfaces of each layer of the second substrate 18. For example, a signal layer that performs transmission and reception of signals, a ground layer, a power source layer, and the like are formed on the each layer.

The semiconductor chip 20 is, for example, a semiconductor of a flip chip mounting type, and is arranged on the third surface 18b. The semiconductor chip 20 has the fourth surface 20a facing the third surface 18b, and the fifth surface 20b opposite to the fourth surface 20a. Further, the semiconductor chip 20 controls, for example, a memory chip 32 (the second electronic component or a NAND type flash memory chip) that is mounted on the first surface 12a of the first substrate 12 on which the semiconductor package 16 is also mounted (see FIG. 1 and FIG. 3).

The semiconductor chip 20 performs data reading and writing with respect to, for example, the memory chip 32, and transmits data to and receives data from external apparatuses (a personal computer, a CPU cores or the like). As shown in FIG. 3, in the present embodiment, for example, four memory chips 32 (memory chips 32a to 32d) are mounted.

The insulator layer 22 covers the fifth surface 20b of semiconductor chip 20 and the side surfaces of the semiconductor chip 20 in a state where the semiconductor chip 20 is mounted on the third surface 18b of the second substrate 18. Accordingly, the semiconductor chip 20 is electrically insulated from the periphery of the second substrate 18. The insulator layer 22 may have a sheet-like shape, or have a coating of insulation resin and the like applied thereto.

Further, when a portion of the semiconductor chip 20 that is required to be electrically insulated from the periphery on the second substrate 18, or when the portion is not required to be insulated, the insulator layer 22 may be omitted. Further, when the heat conduction layer 24 includes a material having insulation property, the insulator layer 22 may be omitted. The same is applicable to the other insulator layer 22 of the other embodiments.

The heat conduction layer 24 is provided so as to cover (contact) the third surface 18b of the second substrate 18 and the fifth surface 20b of the semiconductor chip 20 covered with the insulator layer 22. For example, when the second substrate 18 is viewed from the third surface 18b, the entire surface of the second substrate 18 is covered with the heat conduction layer 24. The heat conduction layer 24 is provided for mainly performing the heat transfer of the heat generated in the semiconductor chip 20, and includes a material of high thermal conductivity.

For example, the heat conduction layer 24 may be configured such that metallic sheet (thin film) may be bonded using an adhesive and the like. Further, the heat conduction layer 24 may be formed using a film forming technique such as sputtering or evaporating. Further, the material of the heat conduction layer 24 is not limited to metal, and any other materials may be used as long as heat transfer may be efficiently performed through the used material.

Another example of the heat conduction layer 24 may include, for example, graphite. The graphite has a structure in which a plurality of planar macromolecules, which is called graphene sheet, is stacked and the graphene sheet has a structure in which benzene rings are arranged on a plane. The graphite has a heat conductivity of very high degree. For this reason, the graphite may be processed into a sheet shape.

The sealing unit 26 (coating material, sealing material, or protecting material) is a member which is located above the second substrate 18 of the heat conduction layer 24, and covers (contacts) at least the heat conduction layer 24. The sealing unit 26 is formed of, for example, a resin material. In FIG. 1 to FIG. 3, the sealing unit 26 has a surface area similar to the surface area of the third surface 18b of the second substrate 18 when seen above the top surface. However, the sealing unit 26 may be formed to cover the side surfaces of the second substrate 18. The sealing unit 26 may include, for example, an epoxy resin and the like.

The sealing unit 26 is provided so as to cover semiconductor chip 20. Therefore, for example, when an impact is exerted to the semiconductor chip 20 from the outside, the semiconductor chip 20 may be protected from the impact, and further the sealing unit 26 may improvement the wet resistance of the semiconductor chip 20.

Further, in the sealing unit 26 formed of a resin material such as an epoxy resin, a surface 26b of the sealing unit 26 may be easily processed in a state where the semiconductor chip 20 is covered with the sealing unit 26 as shown in FIG. 2. For example, the surface 26b of the sealing unit 26 may be shaped into a planer shape. Further, information such as a product number, a manufacturing lot number, and an identification symbol may be formed on the surface 26b, using printing and the like. Further, a coloring matter may be added to a resin material used for the sealing unit 26 and colors of the sealing unit 26 may be freely set. As a result, the design variation of the entire semiconductor package 16 may be increased.

The semiconductor package 16 includes a ball grid array (BGA) in which the solder balls 16a are arranged in a grid-like shape on the second surface 18a of the second substrate 18. Further, the solder ball 16a are melted so that the semiconductor package 16 is electrically connected to a pad (an electrode: not shown) formed on the first surface 12a of the first substrate 12.

Further, a gap is generated due to the solder ball 16a between the first surface 12a of the first substrate 12 and the second surface 18a of the second substrate 18, and the gap may be filled with an under fill agent (not shown in FIG. 2). The under fill agent is formed of, for example, a thermosetting resin, and intrudes into the gap between the first surface 12a and the second surface 18a due to the capillary phenomenon. Therefore, the under fill agent functions as an anti-shocking material against stress such as impacting and bending exerted from the outside, and thus the under fill agent may improve reliability in connection of the solder ball 16a.

Here, as an operation frequency of the semiconductor chip 20 increases, the heat generated in the semiconductor chip 20 increases. For this reason, if the heat radiation of the semiconductor chip 20 is effectively performed, the semiconductor chip 20 may be protected against functional degradation and shortening of product life.

In view of this, the semiconductor device 10 according to the present embodiment has the heat conduction layer 24 which covers the fifth surface 20b of the semiconductor chip 20. Further, a plurality of the second vias 38 penetrating between the second surface 18a and the third surface 18b is formed in the second substrate 18. The heat conduction layer 24 and the first substrate 12 are thermally connected to each other through the second vias 38.

Further, in the present embodiment, the expression “to be thermally connected” means a configuration in which heat transfer is positively performed through media which has a thermal conductivity greater than, for example, that of air (ambient gas). Accordingly, physical contacts between components are not necessarily required.

Generally in a multilayer wiring, the via is a connection area through which wirings of a lower layer and wirings of an upper layer are electrically connected to each other. Further, the via is formed by etching an interlayer insulation film to form an opened via hole and embedding a metallic material into the via hole. As described above, a portion of the second vias 38 formed in the second substrate 18 of the semiconductor package 16 is used for performing electrical connection between the second surface 18a and the third surface 18b in the second substrate 18. However, the other portion of the second vias 38 may be used for transferring the heat generated during driving of the semiconductor chip 20 to the first substrate 12.

A part of the second vias 38 each has one end which is thermally connected to the heat conduction layer 24, and the other end which is thermally connected to one of the solder balls 16a. In this case, the heat conduction layer 24 has a function that transfers the heat generated in the semiconductor chip 20 to a plurality of the second vias 38. Further, a part of the second vias 38 each has one end which is thermally connected to the fourth surface 20a of the semiconductor chip 20, and the other end which is thermally connected to one of the solder balls 16a.

A plurality of the first vias 40 is formed in the first layer 12g of the first substrate 12, and the plurality of the first vias 40 thermally and electrically connects the first surface 12a and the ground layer 42 formed on the second layer 12h. In FIG. 2, the first via 40 is formed to correlate to a position of the solder ball 16a to which the second via 38 thermally and electrically is connected. Further, while not shown in FIG. 2, vias that are electrically connected to the signal layer or the power source layer are also formed, and thus the signal layer or the power source layer is capable of electrically being connected to an external apparatus through a terminal pin 14b of the connector 14. In the present embodiment, the thermal conductivity of the first layer 12g is less than the thermal conductivity of the vias 40. Alternatively, a material that has a thermal conductivity less than those of the vias 40 and the first layer 12g may be formed therebetween.

In the semiconductor device 10 according to such a configuration, when the semiconductor chip 20 is driven to generate a heat, a portion of the generated heat is transferred to the heat conduction layer 24, and the transferred heat is further transferred to the solder ball 16a through the second via 38, and again is thermally transferred to the ground layer 42 through the first via 40. According to the measure described above, the heat generated due to the heating of the semiconductor chip 20 is dissipated. Further, when heat transfer to the first substrate 12 is positively and intendedly performed, the second vias 38 which are thermally connected to the heat conduction layer 24 may be increased in number.

Also, as illustrated in FIG. 2, in the present embodiment, the heat conduction layer 24 includes a heat leading surface 28 (connection surface, exposed surface) which is formed by a portion of the heat conduction layer 24 and exposed at the side surfaces of the sealing unit 26. The heat generated due to driving of the semiconductor chip 20 is also partially transferred through the heat conduction layer 24 and radiated from the heat leading surface 28.

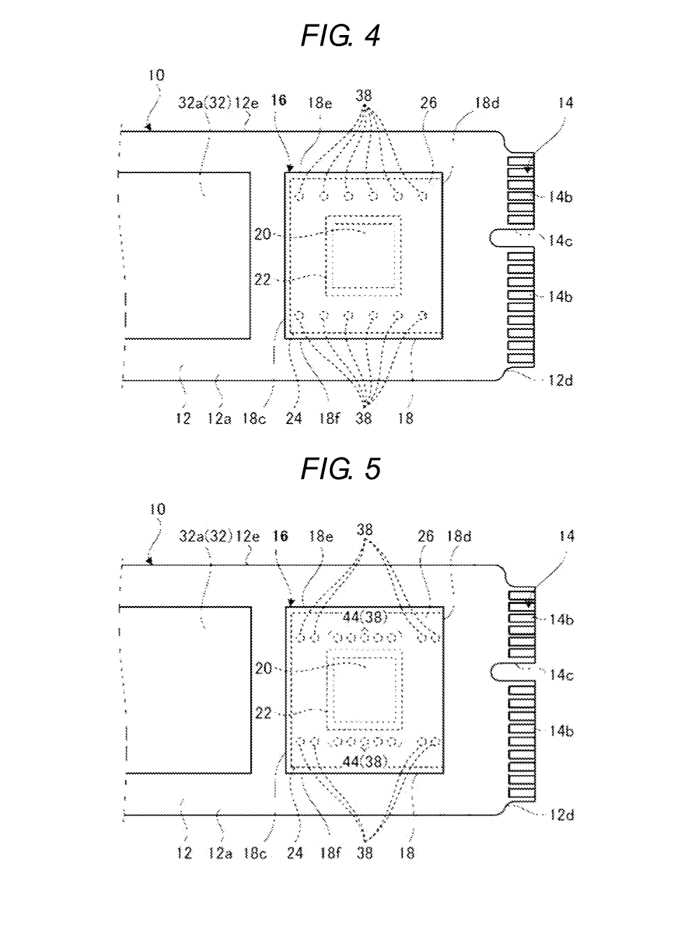

FIG. 4 is a partial plan view of the semiconductor device 10 showing positions in which the second vias 38 are formed in the semiconductor package 16. Further, FIG. 4 shows only the second vias 38 that transfer the heat generated in the semiconductor chip 20 to the first substrate 12, and does not show the vias that performs electrical connection of the semiconductor chip 20.

The heat leading surface 28 is arranged along the third edge 18e and the fourth edge 18f of the second substrate 18. Further, a plurality of the second vias 38 is arranged along the third edge 18e or the fourth edge 18 of the second substrate 18 between the third edge 18e (fourth edge 18f) and the corresponding edge of the semiconductor chip 20. As a result, the heat transferred to a portion of the heat conduction layer 24 proximate to the second edge 18d is radiated to the outside of the semiconductor package 16 through the heat leading surface 28.

On the other hand, the heat transferred to a portion of the heat conduction layer 24 proximate to the third edge 18e and the fourth edge 18f is transferred to the first substrate 12 through the second vias 38, and then to the terminal pin 14b of the connector 14 through the ground layer 42 (see FIG. 2), and radiated to an external apparatus. Further, the second vias 38 may be arranged along the first edge 18c between the first edge 18c facing the memory chip 32(32a) and a corresponding edge of the semiconductor chip 20.

Here, if the heat is thermally transferred to the first substrate 12 at the position of the first edge, the temperature of the first substrate 12 may increase in the vicinity of the memory chip 32a, and as a result, the temperature of the memory chip 32a may be undesirably increased. As shown in FIG. 4, the second vias 38 for heat-transfer is not arranged in the vicinity of the memory chip 32a and thus it is possible to alleviate the thermal influence on the memory chip 32a located close to the semiconductor package 16.

Further, FIG. 4 shows an example in which the second vias 38 are arranged at equal intervals along the third edge 18e and fourth edge 18f, such that the second vias 38 along the third edge 18e is approximately in parallel to, and identical in number to the second vias 38 along the fourth edge 18f. However, the number or positional intervals of the second vias 38 may be appropriately selected according to, for example, a heat distribution of the heat conduction layer 24. Further, according to the disposition of the vias that are electrically connected to the semiconductor chip 20 to transmit and receive signals or supply electrical power, arrangement of the second vias 38, which may transfer the heat, may be determined.

The heat transfer path of the semiconductor device 10 will be described. The heat generated due to the driving of the semiconductor chip 20 is partially transferred to the second substrate 18 through the third surface 18b that is thermally connected to the fourth surface 20a of the semiconductor chip 20. On the other hand, the heat generated in the semiconductor chip 20 is mainly radiated from the fifth surface 20b to the heat conduction layer 24 which is thermally connected to the fifth surface 20b.

Since the heat conduction layer 24 is covered with the sealing unit 26, the heat transferred to the heat conduction layer 24 is transferred to the second vias 38, which has a temperature lower than a portion of the heat conduction layer 24 covered with the sealing unit 26. The heat transferred to the second vias 38 is further transferred to the ground layer 42 of the first substrate 12 through the solder balls 16a and the first vias 40. The heat transferred to the ground layer 42 is further transferred to an external apparatus (a personal computer, a CPU core or the like) connected to the connector 14.

As described above, the semiconductor device 10 according to the embodiment has the heat conduction layer 24 between the second substrate 18 and the sealing unit 26 so as to cover the semiconductor chip 20, which is a main heat generating source. Further, the second via 38 which is thermally connected to the heat conduction layer 24 may cause the heat generated in the semiconductor chip 20 to be thermally transferred to the outside of both the second substrate 18 and the sealing unit 26 (outside of the semiconductor package 16).

As a result, the heat generated in the semiconductor chip (semiconductor package 16) is efficiently thermally transferred and radiated to, for example, an external apparatus or the like, and thus the semiconductor chip 20 may be protected from functional degradation and shortening of product life.

Further, as described in the above embodiment, the heat conduction layer 24 is arranged so as to be located at a position close to or in contact with the semiconductor chip 20, and thus the heat transfer may be efficiently performed.

For example, if the heat conduction layer 24 is not provided and the semiconductor chip 20 and the sealing unit 26 are in direct contact with each other, the generated heat is slowly diffused in the internal portion of the sealing unit 26, and as a result is slowly radiated from the surface of the sealing unit 26. In other words, the heat is more likely to be thermally transferred to another electronic component (for example, the memory chip 32 and the like) supported on the first substrate 12 through the second substrate 18, the solder balls 16a, the first substrate 12, and the like. On the other hand, as described in the present embodiment, in a position close to the semiconductor chip 20 (for example, in a position coming in contact with the semiconductor chip 20), the heat conduction layer 24 is arranged to cause the heat transfer to be efficiently performed as a result.

Further, the heat transfer direction may be easily controlled, by changing the shape of the heat conduction layer 24. For example, the heat may be positively transferred to a location from which heat radiation may be extensive. As a result, it is possible to prevent the heat from being unintendedly transferred to another electronic component.

Further, by disposing the heat conduction layer 24 in a position close to the semiconductor chip 20 (for example, in a position coming in contact with the semiconductor chip 20), the heat generated in the semiconductor chip 20 is efficiently transferred to the outside. As the sealing unit 26 does not need to radiate heat extensively, heat radiation property of the sealing unit 26 may be lowered. In other words, the thickness of the sealing unit 26 may be reduced. As a result, this configuration may lead to a thin and miniature semiconductor package 16 or semiconductor device 10. Further, this configuration may also lead to a thin and miniature electronic apparatus in which such a semiconductor device 10 is mounted.

In other words, the heat conduction layer 24 causes not only the heat generated in the fourth surface 20a of the semiconductor chip 20 but also the heat generated in the fifth surface 20b of the semiconductor chip 20 to be thermally transferred to the solder balls 16a through the second vias 38. As a result, the heat generated in the semiconductor chip 20 may be efficiently and thermally transferred to the first substrate 12.

Further, FIG. 4 shows an example in which the second vias 38 are arranged in a linear form, but the embodiment is not limited to this arrangement. For example, the second vias 38 may be arranged in a form of so called, “staggered arrangement”, that is, a state where the second vias 38 arranged at the first position close to the third edge 18e, and the second via 38 arranged at the second position which is closer to the semiconductor chip 20 than the first position are alternately arranged along the third edge 18e. The second vias 38 arranged along the fourth edge 18f may be also arranged in the same manner.

FIG. 5 is a plan view of a semiconductor device 10 including the second vias 38 arranged in a different manner. The second vias 38 here also causes the heat generated in the semiconductor chip 20 to be thermally transferred to the first substrate 12. Further, a configuration of the semiconductor device 10 other than the arrangement of the second vias 38 is the same as that of the example shown in FIG. 4. Therefore, the portion of the same configuration is not repeatedly described. When the heat radiated from the semiconductor chip is transferred to the heat conduction layer 24, the temperature in the vicinity of the semiconductor chip 20 as the heating source is likely to increase more than that of the portions which are apart from the semiconductor chip 20. To transfer the heat in the vicinity of the semiconductor chip 20, in the example shown in FIG. 5, a via block 44, which is part of the second vias 38 arranged between the third edge 18e (fourth edge 18f) and the semiconductor chip 20, is arranged in the central portion of the third edge 18e (fourth edge 18f), and the via block 44 has a closely spaced vias. In other words, the via block 44 transfers greater amount of heat than the other second vias 38 at the end portion of the third edge 18e (fourth edge 18f). As a result, the via block 44 may transfer the heat efficiently to the first substrate 12.

FIG. 5 shows an example in which the second vias 38 are arranged in a linear form, but the present embodiment is not limited to this arrangement. For example, as long as the second vias 38 are entirely arranged in the form of a closely and distantly spaced arrangement, the other arrangement may also achieve the same effect as the above case. For example, as long as there are a portion in which a plurality of the second vias 38 is arranged in the closely spaced manner and a portion in which the second vias 38 are arranged relatively sparsely, even when a plurality of vias are arranged, for example, in the staggered arrangement form, the same effect as the above arrangement may be attained.

Further, in the present embodiment, as the example of the staggered arrangement, an arrangement in which the second vias 38 arranged in a first position close to the third edge 18e, and the second vias 38 arranged in a second position closer to the semiconductor chip 20 than the first position are alternately arranged along the third edge 18e. The second vias 38 arranged along the fourth edge 18f may be also arranged in the same manner.

Further, in the present embodiment, to dispose the second vias 38 in the “closely spaced” manner means that when the second vias 38 individually have identical heat transfer property, in the direction along the third edge 18e, the intervals between the second vias 38 arranged in an area (end portion side) in the vicinity of two ends of the third edge 18e are relatively longer than the intervals between the second vias 38 arranged in an area (central area) in the vicinity of the center of the third edge 18e.

Further, the vicinity of the center of the third edge 18e may be assumed to correspond to, for example, an area (central area) defined by two intersecting points of lines extending from two end portions of the edge of the semiconductor chip 20 facing the third edge 18e to the third edge 18e. Further, the end portion side of the third edge 18e may be assumed to correspond to the outside area (end portion area) of the central area in the third edge 18e. Further, the central area and the end portion area may be assumed to be explicitly distinguished with each other, and the central area may be assumed to be approximately an area corresponding to the edge, of the semiconductor chip 20, facing the third edge 18e.

### Second Embodiment

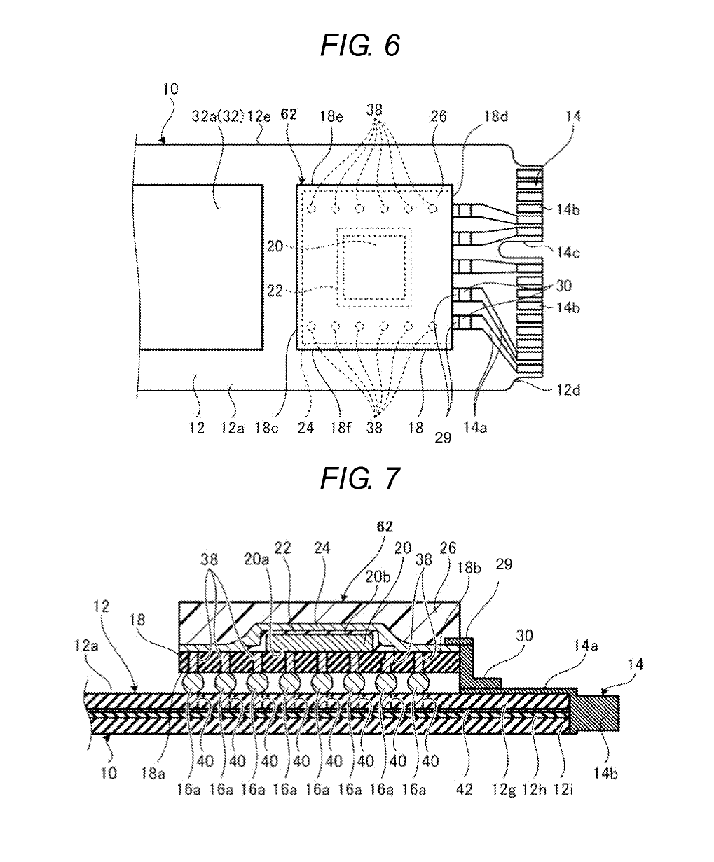

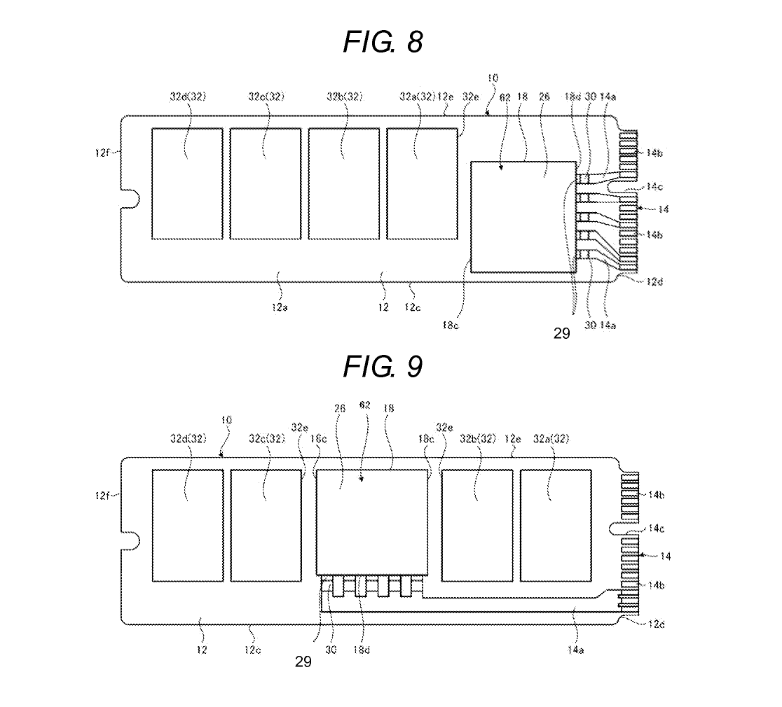

FIG. 6 is a plan view of a semiconductor device 10 according to a second embodiment. FIG. 7 is a cross-sectional view of the semiconductor device 10 according to the second embodiment. Further, FIG. 8 is a plan view showing an example of arrangement relating to the first electronic component (a semiconductor package) and the second electronic component of the semiconductor device 10 according to the second embodiment. Further, the semiconductor device 10 according to the second embodiment is different from the semiconductor device 10 according to the first embodiment only in that the configuration of the semiconductor package 62 is different from that of the semiconductor package 16 shown in FIG. 2. In other words, the semiconductor device 10 according to the second embodiment is the same as the semiconductor device 10 according to the first embodiment in the configuration of the first substrate 12, the configuration of the memory chip 32, and the like, and thus the same configuration are not repeatedly described.

The basic structure of the semiconductor package 62 shown in FIG. 7 is similar to that of the semiconductor package 16 shown in FIG. 2. However, in the present embodiment, a plurality of ground lines 14a is formed on the surface of the first surface 12a of the first substrate 12. Similarly to the ground layer 42, each of ground lines 14a is electrically connected to one of a plurality of terminal pins 14b of the connector 14 and thus connected to an external apparatus.

Further, similarly to the first embodiment, the semiconductor device 10 of the present embodiment has the heat conduction layer 24 which covers the fifth surface 20b of the semiconductor chip 20. Further, the heat conduction layer 24 has the heat leading member 29 to which the heat transfer unit 30 is connected. As shown in FIG. 7, in the present embodiment, the heat leading member 29 is formed as a single component thermally connected to the heat conduction layer 24.

Further, as a modification example, the heat leading member 29 may be formed integrally with the heat conduction layer 24. In this case, the end portion of the second substrate 18 may protrude further as compared with the case in which the end portions of the sealing unit 26 and the heat conduction layer 24 are further formed up to the area of the protruded portion. In other words, a portion of the heat conduction layer 24 is exposed (protruded) from a portion of the sealing unit 26. Further, the exposed portion (protruded portion) in the vicinity of the sealing unit 26 may be used as the heat leading member 29.

In other words, the heat leading member 29 serves as an outlet that transfers the heat generated in the semiconductor chip 20 and transferred to the heat conduction layer 24 or the heat generated in the semiconductor chip 20 and transferred to the heat conduction layer 24 through the second substrate 18, to the outside of an area covered with the sealing unit 26.

The heat transfer unit 30 is located outsides (side surfaces, peripheral portion) the second substrate 18 and the sealing unit 26, and causes the heat conduction layer 24 and the first substrate 12 to be thermally connected with each other. In the present embodiment, the heat transfer unit 30 is thermally connected to the ground line 14a which is formed on the first surface 12a of the first substrate 12. Further, the heat transfer unit 30 is electrically connected to the ground terminal of the semiconductor chip 20 and functions as a component that causes the semiconductor chip 20 to be grounded.

In FIG. 6 to FIG. 8, in order to explain the heat transfer (heat radiation) through the heat transfer unit 30 and the ground line 14a, the heat leading member 29, the heat transfer unit 30, the ground line 14a and the like are shown in exaggerated manner. However, wiring patterns for signal lines or power source lines connecting to the semiconductor chip 20 may be disposed between the ground lines 14a (not shown), and the heat transfer units 30 (heat leading member 29) may be disposed in an intermittent manner (in a state where there are intervals between the heat transfer units). Further, when the ground layer, the signal layer, the power source layer, or the like is formed in the internal portion of the first substrate 12, the ground line 14a may be used for a dedicated heat radiation. In this case, only the ground line 14a may be formed on the first surface 12a.

Further, similar to the first embodiment, the second substrate 18 includes the second vias 38 which penetrate between the second surface 18a and the third surface 18b, and the heat conduction layer 24 and the first substrate 12 are thermally connected to each other through the second vias 38. The semiconductor package 62 is electrically connected to the first surface 12a of the first substrate 12 through the solder balls 16a.

The semiconductor package 62 includes the second substrate 18, the semiconductor chip 20, the insulator layer 22, the heat conduction layer 24, and the sealing unit 26. The semiconductor chip 20, the insulator layer 22, the heat conduction layer 24 and the sealing unit 26, which together configures the semiconductor package 64, are identical to those of the semiconductor package 16, in individual configurations and stacking structures. Further, a gap is formed between the first surface 12a of the first substrate 12 and the second surface 18a of the second substrate 18 due to the solder balls 16a, and the gap may be filled with a under fill agent.

In the semiconductor device 10 having such a configuration, when heat is generated due to driving of the semiconductor chip 20, the generated heat is partially transferred to the ground line 14a through the heat conduction layer 24, the heat leading member 29, and the heat transfer unit 30, and then the heat is transferred to an external apparatus connecting through the terminal pin 14b. Further, the heat transferred to the heat conduction layer 24 is partially transferred to the solder balls 16a through the second via s38, and then to the ground layer 42 through the first vias 40.

In other word, the semiconductor device 10 shown in FIG. 7 includes the first heat transfer path along which the heat generated in the semiconductor chip 20 is thermally transferred to the outside of the semiconductor package 62 through the heat transfer unit 30, and the second heat transfer path along which the heat is thermally transferred to the outside of the semiconductor package 62 through the second vias 38. In other words, the semiconductor package 62 may efficiently achieve the heat radiation of the semiconductor chip 20 through a plurality of the heat transfer paths.

Further, by adjusting the number or the shape of the heat transfer unit 30 and the number or the shape of the second via 38 used for the heat transfer, heat radiation performed through the heat transfer path including the heat transfer unit 30 and heat radiation performed through the heat transfer path including the second vias 38 can be adjusted. For example, when heat transfer to the first substrate 12 needs to be limited, the number of the second vias 38 thermally connected to the first substrate 12 may be decreased so as to increase heat radiation through the first heat transfer path including the heat transfer unit 30. To the contrary, when heat transfer to the first substrate 12 does not need to be limited, the number of the second vias 38 thermally connected to the first substrate 12 may be increased so as to increase heat radiation through the second heat transfer path including the second vias 38.

FIG. 9 is a plan view of the semiconductor device 10 according to a modification example, in which a layout of the semiconductor package 62 and the memory chip 32 is modified. In FIG. 9, the semiconductor package 62 is arranged in the approximately central portion of the first substrate 12, and the memory chip 32 is arranged in the right and left sides of the central portion.

In FIG. 9, memory chips 32a and 32b are arranged near the connector 14 (side surface 12d) and memory chips 32c and 32d are arranged away from the connector 14 (near the side surface 12f), and the semiconductor package 62 is disposed between the memory chips 32a and 32b and the memory chips 32c and 32d. In the semiconductor package 62, the first edges 18c facing the edge portion 32e of the memory chip 32 correspond to two edges opposite to each other, and the edges different from the first edges 18c are arranged to face the side surface 12c or the side surface 12e of the first substrate 12.

FIG. 9 shows an example in which the second edge 18d of the second substrate 18 is arranged to face the side surface 12c. Further, the heat leading member 29 is formed in the second edge 18d and protrudes from the surface of the sealing unit 26, and the heat transfer unit 30 is thermally connected to the heat leading member 29. In FIG. 9, the ground line 14a is connected to the heat transfer unit 30 which is thermally connected to a plurality of heat leading members 29 protruding from the sealing unit 26. The ground line 14a is thermally connected to the terminal pin 14b of the connector 14 and transfer the heat generated in the semiconductor package 62 to the outside of the semiconductor device 10. Further, the ground line 14a shown in FIG. 9 has a width greater and a heat transfer distance longer than that of the ground line 14a shown in FIG. 8. In other words, the amount of heat radiation from the surface of the ground line 14a may be expected to be greater than the amount of heat radiation from the ground line 14a shown in FIG. 8.

In the present embodiment, an air current flowing from the connector 14 (the side surface 12d) towards the side surface 12f may be generated by a fan and the like. Such an air current is capable of suppressing the heat thermally transferred by the ground line 14a to a side (for example, a side close to the side surface 12c) in which the memory chip 32 is not formed from heating the memory chip 32. Further, the heated air does not stay in the periphery of the memory chip 32 and may flow from the side surface 12f to the outside of the semiconductor device 10. As a result, the efficiency of the heat radiation of the semiconductor device 10 may be improved.

Further, also even when the fan is provided near the side surface 12f so as to generate the air current toward the side surface 12d, the same effect may be attained. FIG. 9 shows an example in which the ground line 14a is thermally connected to a plurality of terminal pins 14b located in the end portion of the connector 14, but the ground line 14a may be connected to one terminal pin 14b. Also, the ground line 14a may be connected to the terminal pins 14b of which number is greater than that of the case of FIG. 9. Further, as shown in FIG. 8, the ground line 14a may be connected to the terminal pin 14b located near the side surface 12e which is divided by the slit 14c so as to diffusely distribute the heat transfer paths for the external apparatus side. In this case, the efficiency of the heat radiation in the external apparatus side may be improved.

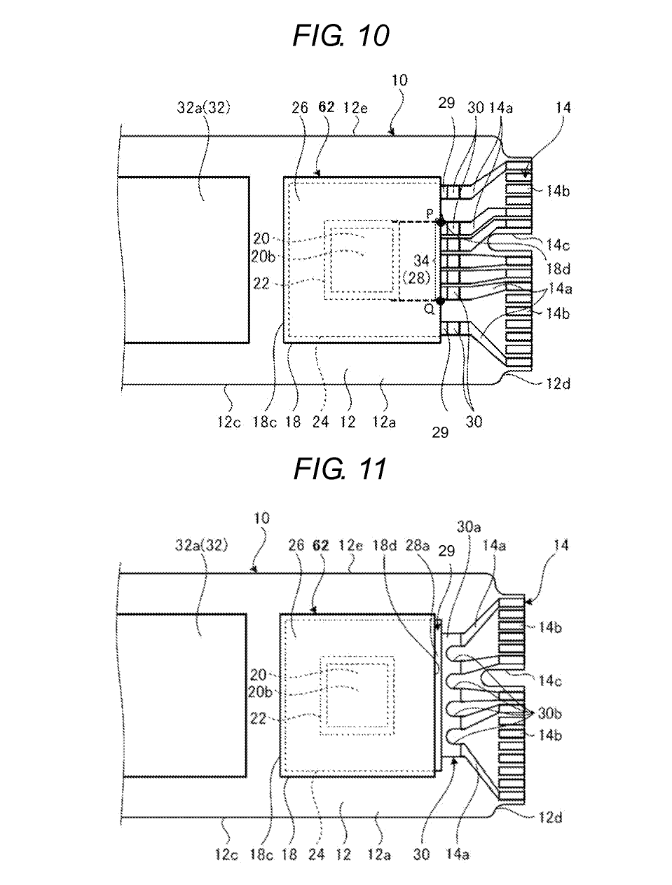

FIG. 10 is a plan view of the semiconductor device 10 according to another modification example, in which arrangement relating to a heat transfer unit 30 (heat leading member 29) is modified. For convenience of description, the via 38 is omitted in FIG. 10, but actually, for example as shown in FIG. 6, the vias 38 are arranged along the third edge 18e and the fourth edge 18f. Further, as shown in the first embodiment, the vias 38 may be arranged in the closely and distantly spaced form.

As shown in FIG. 10, in the semiconductor package 62, the semiconductor chip 20 is arranged approximately in the central portion of the second substrate 18, and an insulator layer 22 is disposed so as to cover the fifth surface 20b of the semiconductor chip 20. Further, when seen from a position above the top surface, approximately the entire portion of the second substrate 18 is covered with the heat conduction layer 24, and the heat conduction layer 24 is covered with the sealing unit 26. In such a configuration, when the semiconductor chip 20 generates heat, the temperature in the central portion of the second edge 18d is likely to increase further as compared with the temperature in the end portion of the edges. In other words, the central portion of the second edge 18d is used to perform the efficient heat transfer so as to also efficiently perform the heat radiation from the second substrate 18.

Therefore, in the modification example of FIG. 10, a connection block 34 is formed in which, in order to deal with the heat distribution of the second substrate 18, the heat leading members 29 are arranged in a further closely spaced form in the central portion as compared with the end portions of the edges of the second edge 18d. Here, to dispose the heat leading members 29 in the “closely spaced” form means that when the heat leading member 29 arranged in the end portion of the second edge 18d and the heat leading members 29 arranged in the central portion individually have identical heat transfer property, the intervals between the heat leading members 29 arranged in an area (the end portion side, the end portion area) in the vicinity of the end portions of the second edge 18d are relatively longer than the intervals between the heat leading members 29 arranged in an area (central area) in the vicinity of the center of the second edge 18d.

Further, in order to arrange the heat leading members 29 in the closely spaced form, the number of the heat leading members 29 per a unit length of the second edge 18d may be greater in the central portion than that in the end portion, or the connectional surface area of the heat leading member 29 in the direction in parallel to the second edge 18d may be greater in the central portion of the second edge 18d than in the end portion of the second edge 18d. Further, the central portion of the second edge 18d may be assumed to correspond to, an area (central area) defined by two intersecting points (point P and point Q In FIG. 10) of lines extending from the edge of the semiconductor chip 20 to the second edge 18d.

Further, the end portion side of the second edge 18d may be defines as the external area (end portion area) of the central area in the second edge 18d. Further, the central area and the end portion area may be explicitly distinguished with each other, and the central area may be defined as an area corresponding to the edge of the semiconductor chip 20 facing the second edge 18d. Accordingly, in the present embodiment, the heat transfer units 30 are arranged to be further closely spaced in the central portion of the second edge 18d when compared with the end portion of the second edge 18d. Such a layout of the heat leading member 29 is capable of performing the heat radiation of a high temperature area of the second substrate 18 (the semiconductor chip 20) to the terminal pin 14b of the connector 14 through the ground line 14a.

FIG. 11 is a plan view of the semiconductor device 10 according to another modification example, in which arrangement relating to a heat transfer unit 30 (heat leading member 29) is modified. Also, in FIG. 11, in the semiconductor package 62, the semiconductor chip 20 is arranged in the substantially central portion of the second substrate 18, and an insulator layer 22 is arranged to cover the fifth surface 20b of the semiconductor chip 20. Further, when seen from a position above the top surface, the approximate entire portion of the second substrate 18 is covered with the heat conduction layer 24, and the heat conduction layer 24 is covered with the sealing unit 26.

In general, as the width (surface area) of a heat transfer path increases, the heat resistance of the heat transfer path decreases and the efficiency of the heat transfer increases. Further, as the width (surface area) of the heat transfer unit 30 increases, the heat radiation from the surface of the heat transfer unit 30 may be more efficiently performed.

In FIG. 11, the heat leading member 29 has a connection bar 28a which extends along the second edge 18d of the second substrate 18. Further, the heat transfer unit 30 has a heat transfer bar 30a which extends along the connection bar 28a. That is, the connection bar 28a and the heat transfer bar 30a are formed in the continuous form along the second edge 18d, and thus the heat transfer path may be increased in width and be decreased in the heat resistance. Accordingly, the efficient heat transfer towards the ground lines 14a may be performed.

As a result, the efficient heat radiation from the semiconductor package 16 through the terminal pin 14b of the connector 14 may be performed. Further, the surface area of heat radiation in the connection bar 28a or the heat transfer bar 30a is increased and thus the efficient heat radiation may be performed.

Further, openings 30b may be formed in the heat transfer bar 30a (heat transfer unit 30). Since the openings 30b are formed in the heat transfer bar 30a, for example, when air flows in the periphery of the semiconductor device 10, a surface area contacting the flowing air is increased, and efficiency of the heat radiation is improved. Further, the shape of the opening 30b is not limited to an arc shape (semi-circular arc shape) in the bottom side (inner side) thereof, and may be a rectangular shape and the like, as shown in FIG. 6.

Meanwhile, as described in FIG. 8 and FIG. 9, the layouts of the semiconductor package 62 and the memory chip 32 may be varied. As the connection position of the heat transfer unit 30 with respect to the semiconductor package 62 changes depending on the layout, the shape of the semiconductor package 62 (position of the heat leading member 29) may need to be changed depending on the layout. In other words, since a dedicated design of the semiconductor package 62 is required for each layout and there are plural kinds of the semiconductor packages 62 which have the same performance, this configuration is not preferable in view of managing components of the semiconductor packages 62.

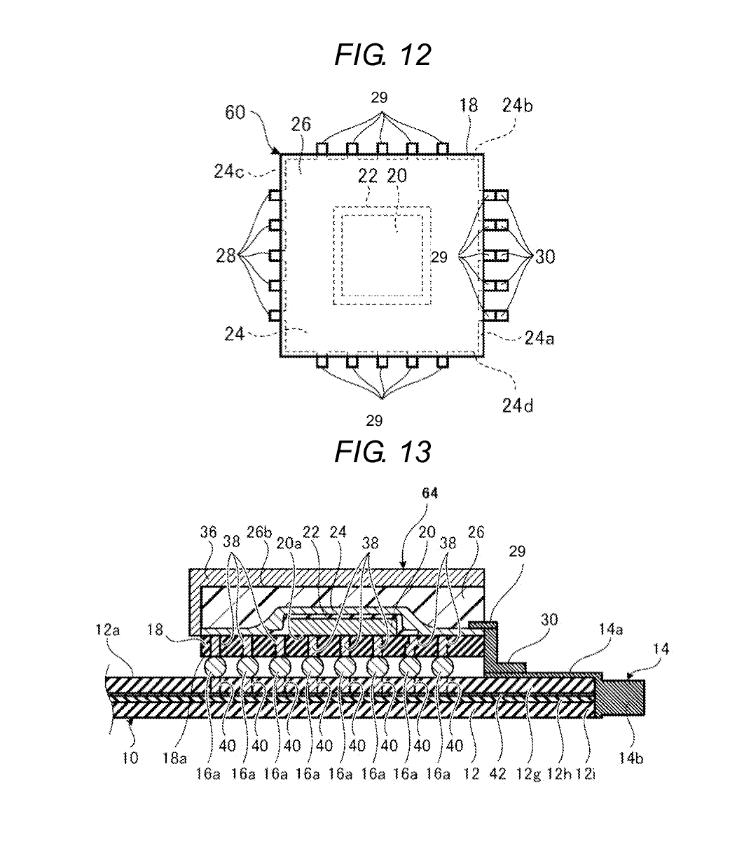

The semiconductor package 60 shown in FIG. 12 has a structure in which the connection position of the heat transfer unit 30 may be selected when the semiconductor package 60 is mounted on the first substrate 12. The semiconductor package 60 has a structure similar to that of the semiconductor package 62 shown in FIG. 7 except that the heat leading members 29 thermally connected to the heat conduction layer 24 are disposed in each of edge portions 24a to 24d of the heat conduction layer 24, and the semiconductor chip 20 mounted on the second substrate 18 is covered with the insulator layer 22.

Further, similarly to the semiconductor package 16, the heat conduction layer 24 of the semiconductor package 60, which is a thin film, is formed on the sealing unit 26 on the side of the second substrate, by adhesive bonding, sputtering, or evaporating. The heat leading members 29 formed in the edge portions 24a to 24d may be integrally formed with the heat conduction layer 24, or the heat leading members 29 that is formed separately from the heat conduction layer 24 may be thermally connected to the heat conduction layer 24.

Further, a plurality of heat leading members 29 protrudes from the sealing unit 26 as shown in FIG. 12. Further, at least a portion of the plurality of the heat leading members 29 and the heat transfer unit 30 are thermally connected to each other so that the heat transfer from the semiconductor package 60 is performed.

FIG. 12 shows an example in which the heat transfer unit 30 is connected to the heat leading member 29 formed in the edge portion 24a. According to another embodiment, the heat transfer unit 30 may be connected to the heat leading member 29 in two or more edge portions (for example, the edge portion 24a and the edge portion 24b) so as to transfer heat.

By arranging the plurality of the heat leading members 29 so as to protrude from the semiconductor package 60, according to the layout of the semiconductor package 60 or the memory chip 32, the connection position of the heat transfer unit 30 with respect to the semiconductor package 60 may be freely selected.

As a result, even if only one type of the semiconductor package 60 is prepared, the heat transfer can be applied to various layouts. Further, when the heat transfer unit 30 is connected to the heat leading members 29 arranged in two or more edge portions, the heat transfer path may be increased and thus degree of freedom in design for heat radiation may be improved.

Further, in FIG. 12, the heat leading member 29 serves as a dummy connection unit to which the heat transfer unit 30 is not connected. In this case, if necessary, the dummy connection unit may be covered with a cover attached thereto so that the dummy connection unit is not exposed or the sealing property of the semiconductor package 60 is improved.

Further, when the heat leading member 29 as a separate component is connected to the heat conduction layer 24, only the heat leading member 29 connected the heat transfer unit 30 may be connected to the heat conduction layer 24. For example, openings may be formed in the sealing unit 26 so that the heat leading members 29 is inserted thereinto, and the heat conduction layer 24 and the heat leading member 29 may be connected to each other through the formed opening. Unused openings may be covered and sealed.

Further, FIG. 12 shows an example in which the same number of the heat leading members 29 is arranged at equal intervals in each of the edge portions 24a to 24d, but the embodiment does not be limited thereto. For example, the heat leading members 29 may be arranged in the closely and distantly spaced form as shown in FIG. 10. Here, to dispose the heat leading member 29 in the closely and distantly spaced form means a localization state where the heat leading members 29 are partly arranged in the closely spaced form, that is, there are a closely spaced portion (a high density area) having a state where the location number of the heat leading member 29 per a unit length of each of the edge portions 24a to 24d is greater than that of other portions and a distantly spaced portion which is an area having a density lower than that of the high density area.

Further, the different numbers of the heat leading members 29 may be arranged for each of the edge portions (24a to 24d), and the connection bar 28a shown in FIG. 11 may be used. Further, the heat leading members 29 shown in FIG. 10 may be arranged in a portion of the edge portions, and the connection bar 28a may be arranged in the other portion of the edge portions.

Further, as shown in FIG. 12, the heat leading member 29 may be provided in each of the edge portions 24a to 24d, or the heat leading member 29 may be disposed in a portion of the edge portions, for example, only in the edge portion 24a and the edge portion 24b, and the heat leading member 29 may be provided in a portion of the edge portions, for example, only in the edge portion 24a and the edge portion 24c. Further, for example, the heat leading heat leading member 29 may be provided only in the edge portion 24d.

### Third Embodiment

FIG. 13 is a cross-sectional view of a semiconductor device 10 according to the third embodiment. Further, same numerals will be assigned to members having the same configuration as those of the other embodiments and the detailed description thereof will not be repeated. A semiconductor package 64 mounted in the semiconductor device 10 includes heat transfer paths of three different types.

The first heat transfer path corresponds to a path along which the heat generated in the semiconductor chip 20 is transferred to the outside of the semiconductor package 64 through the heat conduction layer 24, the heat leading heat leading member 29 and the heat transfer unit 30, and the heat is then transferred to an external apparatus connected to the ground line 14a and the terminal pin 14b of the connector 14 (see the second embodiment).

The second heat transfer path corresponds to a path along which the heat generated in the semiconductor chip 20 is thermally transferred to the ground layer 42 through the second vias 38 connected to the heat conduction layer 24, the solder ball 16a connected to the second vias 38, which is thermally connected to the fourth surface 20a of the semiconductor chip 20, and the first via 40. The heat thermally transferred to the ground layer 42 is transferred to an external apparatus connected to the terminal pin 14b of the connector 14 (refer to the first embodiment).

The third heat transfer path corresponds to a path along which the heat generated in the semiconductor chip 20 is thermally transferred to the outside (the surface 26b of the sealing unit 26) of the semiconductor package 64 through the heat conduction layer 24 and the heat radiating unit 36, and the thermally transferred heat is radiated to the periphery of the semiconductor package 64. Hereinafter, the third heat transfer path will be described.

The basic structure of the semiconductor package 64 shown in FIG. 13 is similar to that of the semiconductor package 62 shown in FIG. 7 except that a heat radiating unit 36 is formed on the surface 26b of the sealing unit 26 (the surface opposite to the rear surface 26a facing the second substrate 18) and thermally connected to the heat conduction layer 24.

The semiconductor package 64 is electrically connected to the first surface 12a of the first substrate 12 through the solder balls 16a. The semiconductor package 64 includes the second substrate 18, the semiconductor chip 20, the insulator layer 22, the heat conduction layer 24, and the sealing unit 26.

The second substrate 18, the semiconductor chip 20, the insulator layer 22, the heat conduction layer 24, and the sealing unit 26, of the semiconductor package 64, are identical to those of the semiconductor package 16 in individual configurations and stacking structures. Further, a gap is formed between the first surface 12a of the first substrate 12 and the second surface 18a of the second substrate 18 due to the solder balls 16a, and the gap may be filled with an under fill agent.

The heat conduction layer 24 has the heat leading member 29 and is thermally connected to the heat transfer unit 30. The heat transfer unit 30 is thermally connected to the ground line 14a formed on the first surface 12a of the first substrate 12. The heat transfer unit 30 is configured to be electrically connected to the ground terminal of the semiconductor chip 20 and function as a component to ground the semiconductor chip 20. The heat generated due to driving of the semiconductor chip 20 is transferred to the heat leading heat leading member 29 through the heat conduction layer 24, and then to the ground line 14a through the heat transfer unit 30.

The heat transferred to the heat transfer unit 30 is partially radiated from the surface of the heat transfer unit 30. Further, the heat transferred to the ground line 14a to which the heat transfer unit 30 is thermally connected is partially radiated from the surface of the ground line 14a. The heat transferred to the ground line 14a is transmitted to an external apparatus (a personal computer, CPU core or the like) which is connected the terminal pin 14b of the connector 14.

In the semiconductor package 64, the heat radiating unit 36 (heat radiating sheet, heat radiating plate, heat radiating plate, or rubber sheet) are thermally connected to the heat conduction layer 24. The heat radiating unit 36 is thermally connected to the heat conduction layer 24, for example, in the first edge 18c, that is, in an edge which is different from the second edge 18d in which the heat leading member 29 connected to the heat transfer unit 30 is formed. Further, the heat radiating unit 36 turns around a side surface of sealing unit 26 and is arranged along the surface 26b of the sealing unit 26 (surface opposite to a surface facing the second substrate 18).

In the present embodiment, when seen from a position above the top surface of the semiconductor package 62, the heat radiating unit 36 is arranged so as to cover the entire portion of the sealing unit 26. The heat radiating unit 36 corresponds to, for example, a resin sheet containing carbon, which may have a low heat resistance. The heat transferred from the heat conduction layer 24 to the heat radiating unit 36 is conducted in the heat radiating unit 36 and radiated from the surface 36a of the heat radiating unit 36.

In the case of the semiconductor package 64, there are three heat transfer paths: the first heat transfer path along which the heat transferred to the heat conduction layer 24 is transferred to the connector 14 through the heat transfer unit 30; the second heat transfer path along which the heat is thermally transferred to the ground layer 42 through the second vias 38, the solder balls 16a, and the first vias 40; and the third heat transfer path along which the heat is radiated to the periphery of the semiconductor device 10 from the heat radiating unit 36.

According to such a configuration, by adjusting the number of the heat transfer units 30 or the surface area of the heat transfer units 30, or the heat resistance or the heat radiating surface area of the heat radiating unit 36, the balance between heat transfer to an external apparatus and heat radiation from the semiconductor device 10 may be adjusted.

For example, when there is a limitation as to the amount of heat radiation to the periphery of the semiconductor device 10, an adjustment may be performed so as to increase the amount of heat transfer to an external apparatus. To the contrary, when there is a limitation as to the amount of heat transfer to an external apparatus, an adjustment may be performed so as to increase the amount of heat radiation to the periphery of the semiconductor device 10.

Further, the surface 36a of the heat radiating unit 36 (surface opposite to a surface contacting the surface 26b of the sealing unit 26) may be, for example, a planar surface. Further, information such as a product number, a manufacturing lot number, an identification symbol, and the like may be appended on the surface 36a, using printing and the like. Further, a coloring material may be added to a material used for forming the heat radiating unit 36 so as to change colors of the heat radiating unit 36, and thus the design property of the entire semiconductor package 64 may be improved. Further, any type of the heat radiating unit 36 may be applied if a low heat resistance and sufficient heat radiating surface area are secured, and the same effect described above may be attained.

According to the semiconductor device 10 in which the semiconductor package 64 described above is mounted, there are three heat transfer paths for the heat generated in the semiconductor chip 20. As a result, the heat radiation of the semiconductor chip 20 may be further efficiently performed. Further, the distribution of the amount of heat transfer (the amount of heat radiation) for each heat transfer path may be changed, and thus degree of freedom in design for heat radiation may be improved. As a result, for example, according to a specification of an external apparatus (for example, a personal computer, a CPU core or the like) which uses the semiconductor device 10, a heat transfer path may be selected.

Further, among the configuration shown in FIG. 13, for example, the heat leading member 29, the heat transfer unit 30, and the ground line 14a, i.e., the first heat transfer path may be omitted, and the heat may be transferred through the second heat transfer path and the third heat transfer path. Alternatively, any combination of the heat transfer paths selected from the first heat transfer path to the third heat transfer path, or any modification of the first heat transfer path to the third heat transfer path may be applicable.

### Fourth Embodiment

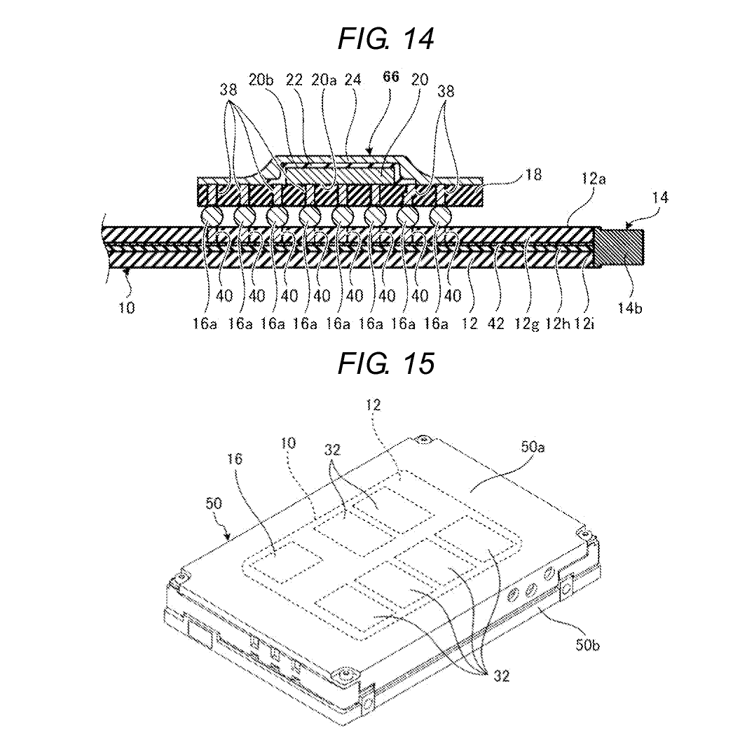

FIG. 14 is a cross-sectional view of a semiconductor device 10 according to a fourth embodiment. Further, same numerals will be assigned to members having the same configuration as those of the other embodiments and the detailed description thereof will not be repeated. A semiconductor package 66 of the semiconductor device 10 shown in FIG. 14 has a structure in which the heat generated in the semiconductor chip 20 is thermally transferred to the ground layer 42 of the first substrate 12 mainly through the second vias 38 and the solder balls 16a, and the heat is transferred to an external apparatus connected to the connector 14.

The second vias 38 are used to transfer the heat generated during driving of the semiconductor chip 20 to the first substrate 12. Each of a portion of the second vias 38 has one end which is thermally connected to the heat conduction layer 24 and the other end which is thermally connected to one of the solder balls 16a. In this case, the heat conduction layer 24 has a function that distributes the heat generated in the semiconductor chip 20 to a plurality of the second vias 38.

Further, each of the other portion of the second vias 38 has one end thermally connected to the fourth surface 20a of the semiconductor chip 20 and the other end thermally connected to one of the solder balls 16a. In other words, the heat conduction layer 24 conducts not only the heat generated in the fourth surface 20a of the semiconductor chip 20 and but also the heat generated in the fifth surface 20b of the semiconductor chip 20 to the solder balls 16a through the second vias 38. As a result, the heat generated in the semiconductor chip 20 may be efficiently and thermally transferred to the first substrate 12.

Further, in the present embodiment, the heat conduction layer 24 is not covered with a resin or the like. For this reason, the heat generated in the vicinity of the fifth surface 20b of the semiconductor chip 20 is rapidly radiated to the outside through the heat conduction layer 24.

In the semiconductor device 10 in which the semiconductor package 66 described above is mounted, the heat generated in the semiconductor chip 20 is mainly transferred to an external apparatus connected to the connector 14 through the first substrate 12. Further, the heat generated in the semiconductor chip 20 is partially radiated to the outside from the entire heat conduction layer 24.

As described above, in the semiconductor package 66 according to the present embodiment, the heat generated in the semiconductor chip 20 is rapidly radiated. Accordingly, when the amount of heat radiation of the semiconductor chip 20 is great and rapid heat radiation is required, the configuration of the present embodiment may be appropriately used.

### Fifth Embodiment

FIG. 15 is a perspective view of an electronic apparatus 50 according to a fifth embodiment. The electronic apparatus 50 is, for example, an external-type SSD apparatus. The semiconductor device 10 is mounted in an internal space of the electronic apparatus 50, which is formed by a first housing 50a and a second housing 50b. On the first substrate 12, the semiconductor package 16 and a plurality of memory chips 32 are mounted.

The heat radiating structure described above causes the heat generated in the semiconductor chip 20, which is included in the semiconductor package 16, to be thermally transferred to structural components of the electronic apparatus 50 or the first housing 50a and the second housing 50b and radiated therefrom.

As a result, the semiconductor device 10 may maintain a range of temperature which is appropriate for operation, and thus the electronic apparatus 50 may assuredly perform excellent operation. Further, the layout of the semiconductor package 16 or the memory chip 32, which is mounted on the first substrate 12 in the electronic apparatus 50 is shown only by way of an example, and according to a required capacity of memory, a size of the housing of the electronic apparatus 50 or the like, the layout may be appropriately modified. Further, a plurality of the first substrates 12 may be mounted in the electronic apparatus 50.

Further, the semiconductor package 16 described in the present embodiment may be appropriately replaced with the other semiconductor packages in each of the embodiments described above.

### Sixth Embodiment

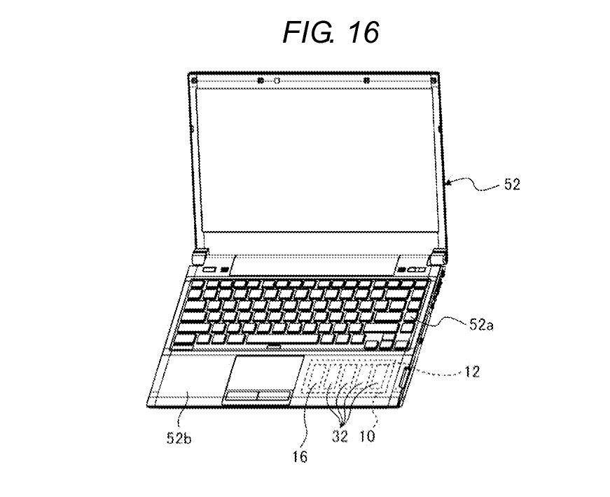

FIG. 16 is a perspective view of an electronic apparatus 52 according to a sixth embodiment. The electronic apparatus 52 is, for example, a personal computer. The semiconductor device 10 is mounted, for example, in the internal space below a palm rest 52b in the front of a key board 52a, and the semiconductor package 16 and a plurality of memory chips 32 are mounted on the first substrate 12.

The radiating structure described above causes the heat generated in the semiconductor chip 20, which is included in the semiconductor package 16, to be radiated through structural components of the electronic apparatus 52. Also, airflow generated by a fan built in the electronic apparatus 52 causes the heat to be discharged with exhaust gas from an outlet (not shown) of the electronic apparatus 52. As a result, the semiconductor device 10 may maintain a range of temperature appropriate for operation, and thus the electronic apparatus 52 may more reliably perform excellent operation.

Further, the layout of the semiconductor package 16 or the memory chip 32, which is mounted on the first substrate 12 of the electronic apparatus 52 is shown only by way of an example, and according to a required capacity of memory, a size of mounting space for the semiconductor device 10 in the electronic apparatus 52, or the like, the layout may be appropriately modified. Further, a plurality of the first substrate 12 may be mounted in the electronic apparatus 52.

As described above, a semiconductor device according to an embodiment includes, for example, a first substrate which has a first surface, a second substrate which is provided on a first surface and has a second surface facing the first surface and a third surface opposite to the second surface, a first electronic component which is provided on the third surface and has a fourth surface facing the third surface and a fifth surface opposite to the fourth surface, a heat conduction layer which covers the third surface and the fifth surface, a sealing unit which is located opposite to the second substrate and covers at least the heat conduction layer, and a heat transfer unit to which the heat conduction layer and the first substrate are thermally connected and which is located outside the second substrate and the sealing unit.

According to this configuration, for example, the heat generated in the first electronic component may be thermally transferred to the outside of the sealing unit through the heat conduction layer and the heat transfer unit. As a result, the heat radiation of the first electronic component covered with the sealing unit may be efficiently performed.

Further, the first substrate of the semiconductor device according to an embodiment may have the second electronic component, for example, on the first surface, the second substrate has the first edge facing the second electronic component and the second edge different from the first edge, and the heat transfer unit may be disposed along the second edge. According to this configuration, for example, when the heat generated in the first electronic component is thermally transferred, the heat transfer path may be arranged away from the second electronic component, and thus the second electronic component is protected from being subjected to the heat transferred from the first electronic component.

Further, the heat conduction layer and the first substrate of the semiconductor device according to an embodiment may be thermally connected to, for example, a plurality of the heat transfer units. According to this configuration, for example, the heat generated in the first electronic component may be efficiently and thermally transferred to the first substrate through the heat conduction layer. Further, the number of the heat transfer units is adjusted to adjust the efficiency of the heat transfer.

Further, the plurality of heat transfer units of the semiconductor device according to an embodiment may be arranged, for example, in the further closely spaced form in the central portion of an edge of the second substrate as compared with the end portions of the second substrate. According to this configuration, since the efficiency of the heat transfer increases in a position close to the first electronic component as a heating source, the heat radiation may be efficiently performed.

The heat transfer unit of the semiconductor device according to an embodiment may have an opening. According to this configuration, for example, the surface area of the heat transfer unit may be increased, and thus the efficiency of the heat radiation from the surface of the heat transfer unit may be improved.

Further, in the sealing unit of the semiconductor device of an embodiment, the heat radiating unit, which is thermally connected to the heat conduction layer, may be disposed on the surface of the sealing unit. According to this configuration, the heat generated in the first electronic component and transferred to the heat conduction layer may be radiated from the heat radiating unit to the ambient air of the periphery of the semiconductor device, and thus the efficiency of heat radiation of the first electronic component may be improved. Further, since the heat transfer path using the heat transfer unit and the heat transfer path using the heat radiating unit are formed, a degree of freedom in design for heat radiation may be increased.

Further, a semiconductor device according to an embodiment includes, for example, connection units which are thermally connected to the heat conduction layer, and connected to the plurality of the heat transfer units, and the heat conduction layer and the heat transfer unit may be thermally connected to each other through at least one of the connection units. According to this configuration, options for selecting connection positions in which the heat transfer units is connected to the heat conduction layer are increased, and thus the layout of components to be mounted in the semiconductor device may be easily performed.

Further, the second substrate of the semiconductor device according to an embodiment includes vias which penetrate between the second surface and the third surface, and the heat conduction layer and the first substrate may be thermally connected to each other through the vias. According to this configuration, for example, the heat generated in the first electronic component, which is mounted in the second substrate, may be thermally transferred to the first substrate through the vias of the second substrate. As a result, the efficiency of the heat radiation of the first electronic component may be improved. Further, since the heat transfer path using the heat transfer unit and the heat transfer path using the vias are formed, a degree of freedom in design for heat radiation may be increased.

Further, the semiconductor device according to an embodiment includes, for example, the first substrate which has the first surface, the second substrate which is provided on the first surface and has the second surface facing the first surface and the third surface located opposite to the second surface, the first electronic component which is provided on the third surface and has the fourth surface facing the third surface and the fifth surface opposite to the fourth surface, the heat conduction layer which contacts the third surface and the fifth surface, and the sealing unit which is located opposite to the second substrate and contacts the heat conduction layer and at which a portion of the heat conduction layer is exposed. According to this configuration, for example, the heat generated in the first electronic component is thermally transferred to the outside of the sealing unit through the heat conduction layer. As a result, the heat radiation of the first electronic component covered with the sealing unit may be efficiently performed.

Further, the semiconductor device according to an embodiment may be mounted in an electronic apparatus. According to this configuration, for example, as the efficiency of heat radiation in the semiconductor device becomes improved, the efficient of heat radiation in the electronic apparatus in which the semiconductor device is mounted may be improved accordingly. As a result, the reliability of the electronic apparatus may be improved.

Further, a semiconductor device according to an embodiment includes, for example, the first substrate which has the first surface, the second substrate which is provided on the first surface and has the second surface facing the first surface and the third surface opposite to the second surface, the first electronic component which is provided on the third surface and has the fourth surface facing the third surface and the fifth surface opposite to the fourth surface, the heat conduction layer which covers the third surface and the fifth surface, the sealing unit which is opposite to the second substrate and covers at least the heat conduction layer, and the heat radiating unit which is thermally connected to the heat conduction layer and is located in the surface of the sealing unit. According to this configuration, the heat which is generated, for example, in the first electronic component and is transferred to the heat conduction layer may be radiated from the heat radiating unit to the ambient air of periphery of the semiconductor device, and thus the efficiency of the first electronic component may be improved.

Further, the semiconductor device according to an embodiment includes, for example, the first substrate which has the first surface, the second substrate which is provided on the first surface and has the second surface facing the first face and the third surface opposite to the second surface, the first electronic component which is provided on the third surface and has the fourth surface facing the third surface and the fifth surface opposite to the fourth surface, the heat conduction layer which covers the third surface and the fifth surface, and vias which penetrate through the second surface and the third surface of the second substrate and causes the heat conduction layer and the first substrate to be thermally connected to each other. According to this configuration, for example, the heat generated in the first electronic component, which is mounted in the second substrate, may be thermally transferred to the first substrate through the vias of the second substrate. Therefore, the efficiency of the heat radiation of the first electronic component may be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first substrate including a surface layer and a ground layer, the surface layer including a plurality of first vias that is exposed on a surface of the first substrate and electrically connected to the ground layer;
a second substrate disposed on the first substrate and including a plurality of second vias penetrating through the second substrate;
a plurality of conduction elements, each disposed between one of the first vias and one of the second vias;
a semiconductor device unit disposed on the second substrate; and
a heat transfer layer covering the semiconductor device unit and in contact with the second vias at a periphery of the semiconductor device unit, such that heat generated by the semiconductor device unit is transferred to the ground layer, through the heat transfer layer, the second vias, the conduction elements, and the first vias.

2. The semiconductor device according to claim 1, wherein
the plurality of second vias includes second vias arranged in a line, and
a distance between two adjacent second vias arranged in the line at a position closer to the center of the second substrate along the line is smaller than a distance between two adjacent second vias arranged in the line at a position farther from the center of the second substrate.

3. The semiconductor device according to claim 1, wherein
the plurality of second vias includes second vias arranged in a line extending in a longitudinal direction of the first substrate.

4. The semiconductor device according to claim 1, further comprising:
a semiconductor memory unit disposed on a surface of the first substrate on which the semiconductor device unit is disposed.

5. The semiconductor device according to claim 4, wherein
the plurality of second vias includes second vias arranged in a line extending towards the semiconductor memory unit, and
a distance between two adjacent second vias arranged in the line at a position closer to the semiconductor memory unit is smaller than a distance between two adjacent second vias arranged in the line at a position farther from the semiconductor memory unit.

6. The semiconductor device according to claim 4, wherein
the first substrate includes a host connector on an edge of the first substrate, and
the semiconductor device unit is disposed between the host connector and the semiconductor memory unit.

7. The semiconductor device according to claim 4, wherein
the semiconductor device unit is a memory controller configured to control the semiconductor memory unit.

8. The semiconductor device according to claim 1, wherein
the first substrate includes a host connector on an edge of the first substrate, and
the ground layer is electrically connected to the host connector.

9. The semiconductor device according to claim 8, wherein
the plurality of second vias includes second vias arranged in a line extending towards the host connector, and
a distance between two adjacent second vias arranged in the line at a position closer to the host connector is smaller than a distance between two adjacent second vias arranged in the line at a position farther from the host connector.

10. The semiconductor device according to claim 8, further comprising:
a heat transfer member that is in contact with a side surface of the heat transfer layer and wiring that is formed on the surface of the first substrate and electrically connected to the host connector, such that heat is transferred from the heat transfer layer to the host connector through the heat transfer member and the wiring.

11. The semiconductor device according to claim 10, wherein
the wiring extends between the host connector and the second substrate.

12. The semiconductor device according to claim 1, further comprising:
a sealing layer covering the heat transfer layer.

13. The semiconductor device according to claim 12, further comprising:
a second heat transfer layer disposed above the sealing layer and in contact with a side surface of the heat transfer layer.

14. The semiconductor device according to claim 1, wherein
an outer surface of the sealing layer is exposed.

15. A method for transferring heat generated in a semiconductor device including a first substrate including a surface layer and a ground layer, a second substrate disposed on the first substrate, and a semiconductor device unit disposed on the second substrate,
transferring heat generated by the semiconductor device unit to a heat transfer layer covering the semiconductor device unit;
transferring heat from the heat transfer layer to a plurality of vias formed in the second substrate, which is in contact with the heat transfer layer at a periphery of the semiconductor device unit; and
transferring heat from the vias in the second substrate to a plurality of vias formed in the surface layer, and then to the ground layer in contact with the vias in the surface layer.

16. The method according to claim 15, wherein
the semiconductor device further includes a semiconductor memory unit disposed on a surface of the first substrate on which the semiconductor device unit is disposed, and
the heat generated by the semiconductor layer is transferred away from the semiconductor memory unit.

17. The method according to claim 16, wherein
the semiconductor device unit is a memory controller configured to control the semiconductor memory unit.

18. The method according to claim 15, wherein
the first substrate includes a host connector on an edge of the first substrate, and
the heat is transferred from the ground layer towards the host connector.

19. The method according to claim 15, further comprising:
transferring heat from the heat transfer layer to a heat transfer member that is in contact with a side surface of the heat transfer layer, and then to a wiring formed on the surface of the first substrate.

20. The method according to claim 15, wherein the semiconductor device further includes a sealing layer covering the heat transfer layer, the method further comprising:
transferring heat from the heat transfer layer to a second heat transfer layer disposed above the sealing layer and in contact with a side surface of the heat transfer layer.
